(19) United States
(12) Patent Application Publication
(10) Pub. No.: US 2026/0304718 A1
(43) Pub. Date: Oct. 1, 2026

(54) DISPLAY DEVICE

(71) Applicant: LG Display Co., Ltd., Seoul (KR)

(72) Inventor: DongWon Jang, Paju-si (KR)

(73) Assignee: LG Display Co., Ltd., Seoul (KR)

(21) Appl. No.: 19/566,369

(22) Filed: Mar. 13, 2026

(30) Foreign Application Priority Data
Apr. 1, 2025 (KR) 10-2025-0042212

(51) Int. Cl. H05K 7/20; H05K 5/00; H05K 9/00

(52) U.S. Cl. CPC H05K 7/20963; H05K 5/0018; H05K 9/0024

(57) ABSTRACT

The present disclosure provides a display device including a display panel in which a plurality of subpixels are disposed, a power management circuit for supplying driving voltage to the plurality of subpixels, a printed circuit board disposed to overlap with the power management circuit, and a heat insulator disposed between the printed circuit board and the display panel and overlapping with at least a portion of the power management circuit.

### CROSS REFERENCE TO RELATED APPLICATION

This application claims priority from Korean Patent Application No. 10-2025-0042212, filed on Apr. 1, 2025 in the Korean Intellectual Property Office, which is hereby incorporated by reference for all purposes as if fully set forth herein.

### TECHNICAL FIELD

The present disclosure relates to electronic devices with displays, and more specifically, to display devices.

### BACKGROUND

In today's information society, display devices for presenting images or visual information to users are increasingly important. The needs for such display devices have caused display technology to be rapidly developed, and various types of display devices, such as a liquid crystal display (LCD) device, an organic light emitting diode (OLED) display device, and the like, have been developed and utilized.

Among these display devices, organic light emitting display devices using self-emissive organic light emitting diodes (OLED) can exhibit high response speed and present advantages in contrast ratio, emission efficiency, luminance, viewing angle, and the like, compared with other types of display devices such as liquid crystal display (LCD) devices and the like.

The organic light emitting display devices may include a structure where a respective organic light emitting diode is included in each of a plurality of subpixels SP disposed in a display panel. Based on such a structure, the organic light emitting display devices can control luminance and display images presented by each subpixel by allowing the organic light emitting diode to emit light through the control of a current flowing through, or a current applied to, the organic light emitting diode.

Display devices may include various circuits configured to deliver voltages to a plurality of subpixels. The circuits included in the display devices may emit heat while supplying current and voltage to the subpixels. Such circuits can age through use, and thereby, the lifetime of the circuits or display devices can be reduced. To address these issues, work has been progressing on dissipating or managing heat.

The description provided in the discussion of the related art section should not be assumed to be prior art merely because it is mentioned in or associated with that section. The discussion of the related art section may include information that describes one or more aspects of the subject technology, and the description in this section does not limit the present disclosure.

### SUMMARY

One or more aspects of the present disclosure may provide a display device including a heat insulator configured to reduce or prevent the passage of heat emitted from a power management circuit.

One or more aspects of the present disclosure may provide a display device that includes a heat insulator, and thereby is capable of reduce or prevent the degradation of subpixels or reducing a degree to which subpixels degrade. One or more aspects of the present disclosure may provide a display device that includes a structure where subpixels are driven such that the degradation of subpixels is reduced or minimized, and thereby is capable of being driven with low power.

Aspects, examples, and embodiments provided in the present disclosure are not limited to the foregoing description, and additional aspects, examples, and embodiments provided in the present disclosure will become apparent to those skilled in the art from the following description.

According to one or more example embodiments of the present disclosure, a display device can be provided that includes a display panel in which a plurality of subpixels are disposed, a power management circuit for supplying one or more driving voltages to the plurality of subpixels, a printed circuit board disposed to overlap with the power management circuit, and a heat insulator disposed between the printed circuit board and the display panel and overlapping with at least a portion of the power management circuit.

In one or more aspects, the display device may include a heat insulator, and the heat insulator may include, for example. a heat dissipator, a heat shielder, and an impact absorber.

According to one or more aspects of the present disclosure, a display device may be provided that is capable of being driven with low power based on a structure where the degradation of subpixels can be reduced or minimized.

Effects or advantages from aspects, examples, and embodiments described herein are not limited thereto, and additional effects or advantages will become apparent to those skilled in the art from the following description.

It is to be understood that both the foregoing general description and the following detailed description are exemplary and explanatory and are intended to provide further explanation of the inventive concepts as claimed.

### BRIEF DESCRIPTION OF THE DRAWINGS

The accompanying drawings, which are included to provide a further understanding of the disclosure and are incorporated in and constitute a part of the disclosure, illustrate aspects of the disclosure and together with the description serve to explain principles of the disclosure. In the drawings:

FIG. 1 illustrates a system configuration of an example display device according to aspects of the present disclosure;

FIG. 2 is an example front view of the display device in an unbent state according to aspects of the present disclosure;

FIG. 3 is an example rear view of the display device in the unbent state according to aspects of the present disclosure;

FIG. 4 is an example enlarged view of area A of FIG. 3 according to aspects of the present disclosure;

FIG. 5 illustrates an example viewing surface of the display device according to aspects of the present disclosure;

FIG. 6 is an enlarged view of area A of FIG. 3 based on an example where the display device includes a heat insulator according to aspects of the present disclosure;

FIG. 7 illustrates an example arrangement relationship of a printed circuit board, a heat insulator, and an adhesive included in the display device according to aspects of the present disclosure;

FIG. 8 is an example cross-sectional view of the display device in a bent state in an area where an adhesive is disposed according to aspects of the present disclosure;

FIG. 9 is an example cross-sectional of the display device in a bent state in an area where a heat insulator is disposed according to aspects of the present disclosure;

FIG. 10 is an example graph showing changes in optical characteristics over heat generation time according to aspects of the present disclosure; and

FIG. 11 is an example diagram showing changes in temperature of the display device depending on the presence or absence of a heat insulator according to aspects of the present disclosure.

Throughout the drawings and the detailed description, unless otherwise described, the same drawing reference numerals should be understood to refer to the same elements, features, and structures. The relative size and depiction of these elements may be exaggerated for clarity, illustration, and convenience.

### DETAILED DESCRIPTION

Reference will now be made in detail to example embodiments of the present disclosure, examples of which may be illustrated in the accompanying drawings. In the following description, the structures, embodiments, implementations, methods and operations described herein are not limited to the specific example or examples set forth herein and may be changed as is known in the art, unless otherwise specified. Like reference numerals designate like elements throughout, unless otherwise specified. Names of the respective elements used in the following explanations are selected only for convenience of writing the specification and may thus be different from those used in actual products. Further, in the following description of examples or embodiments of the present disclosure, detailed descriptions of well-known functions and components incorporated herein will be omitted or may be briefly provided when it is determined that the description may make the subject matter in some embodiments of the present disclosure rather unclear. The terms such as “including”, “having”, “containing”, “constituting” “make up of”, and “formed of” used herein are generally intended to allow other components to be added unless the terms are used with the term “only”. As used herein, singular forms are intended to include plural forms unless the context clearly indicates otherwise.

Advantages and features of the present disclosure, and implementation methods thereof will be clarified through following example embodiments described with reference to the accompanying drawings. The present disclosure may, however, be embodied in different forms and should not be construed as limited to the example embodiments set forth herein. Rather, these example embodiments may be provided so that this disclosure may be sufficiently thorough and complete to assist those skilled in the art to fully understand the scope of the present disclosure. Further, the present disclosure is only defined by scopes of claims.

Although the terms “first,” “second,” A, B, (a), (b), and the like may be used herein to describe various elements, these elements should not be interpreted to be limited by these terms as they are not used to define a particular order or precedence. These terms are used only to distinguish one element from another. For example, a first element could be termed a second element, and, similarly, a second element could be termed a first element, without departing from the scope of the present disclosure.

When it is mentioned that a first element “is connected or coupled to”, “contacts”, “overlaps with”, or the like a second element, it should be interpreted that, not only can the first element “be directly connected or coupled to”, “directly contact”, or “directly overlap with” the second element, but a third element can also be “interposed” between the first and second elements, or the first and second elements can “be connected or coupled to”, “contact”, “overlap with”, or the like each other via a fourth element. Here, the second element may be included in at least one of two or more elements that “are connected or coupled to”, “contact”, “overlap with”, or the like each other.

Where positional relationships are described, for example, where the positional relationship between two parts is described using “on,” “over,” “under,” “above,” “below,” “beside,” “next,” or the like, one or more other parts may be located between the two parts unless a more limiting term, such as “immediate(ly),” “direct(ly),” or “close(ly)” is used. For example, where an element or layer is disposed “on” another element or layer, a third element or layer may be interposed therebetween. Furthermore, the terms “left,” “right,” “top,” “bottom, “downward,” “upward,” “upper,” “lower,” and the like refer to an arbitrary frame of reference.

In describing a temporal relationship, when the temporal order is described as, for example, “after,” “subsequent,” “next,” and “before,” a case that is not continuous may be included unless a more limiting term, such as “just,” “immediate(ly),” or “direct(ly)” is used

Any implementation described herein as an “example” is not necessarily to be construed as preferred or advantageous over other implementations.

In addition, when any dimensions, relative sizes and the like. are mentioned, it should be considered that numerical values for an elements or features, or corresponding information (e.g., level, range, and the like) include a tolerance or error range that may be caused by various factors (e.g., process factors, internal or external impact, noise, and the like) even when a relevant description is not specified. Further, the term “may” fully encompasses all the meanings of the term “can”.

The expression of a first element, a second elements “and/or” a third element should be understood as one of the first, second and third elements or as any or all combinations of the first, second and third elements. By way of example, A, B and/or C can refer to only A; only B; only C; any or some combination of A, B, and C; or all of A, B, and C.

In the following description, various example aspects of the present disclosure are described in detail with reference to the accompanying drawings. With respect to reference numerals to elements of each of the drawings, the same elements may be illustrated in other drawings, and like reference numerals may refer to like elements unless stated otherwise. The same or similar elements may be denoted by the same reference numerals even though they are depicted in different drawings. In addition, for convenience of description, a scale, dimension, size, and thickness of each of the elements illustrated in the accompanying drawings may be different from an actual scale, dimension, size, and thickness, and thus, aspects of the present disclosure are not limited to a scale, dimension, size, and thickness illustrated in the drawings.

Unless otherwise defined, all terms (including technical and scientific terms) used herein have the same meaning as commonly understood by one of ordinary skill in the art to which example embodiments belong. It will be further understood that terms, such as those defined in commonly used dictionaries, should be interpreted as having a meaning for example consistent with their meaning in the context of the relevant art and should not be interpreted in an idealized or overly formal sense unless expressly so defined herein. For example, the term “part” or “unit” may apply, for example, to a separate circuit or structure, an integrated circuit, a computational block of a circuit device, or any structure configured to perform a described function as should be understood to one of ordinary skill in the art.

Rather, these embodiments may be provided so that this disclosure may be sufficiently thorough and complete to assist those skilled in the art to fully understand the scope of the present disclosure. Furthermore, the present disclosure is only defined by scopes of claims.

It will be apparent to those skilled in the art that various modifications and variations can be made in the display device of the present disclosure without departing from the technical idea or scope of the disclosures. Thus, it is intended that the present disclosure covers the modifications and variations of this disclosure provided they come within the scope of the appended claims and their equivalents.

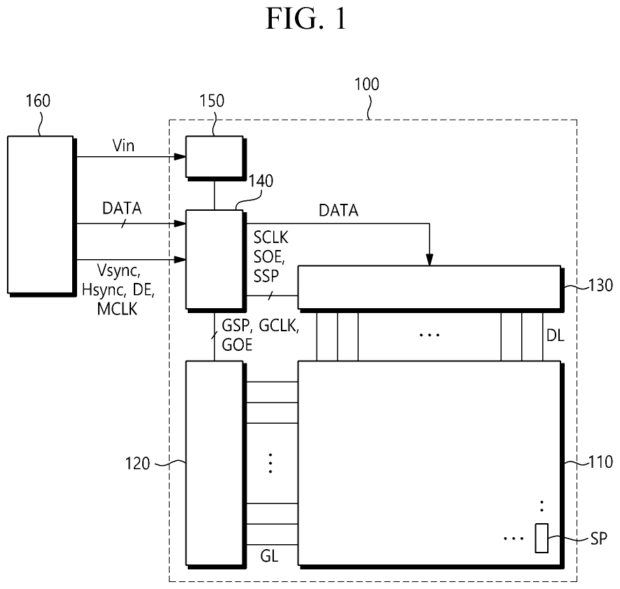

FIG. 1 illustrates a system configuration of an example display device 100 according to aspects of the present disclosure.

Referring to FIG. 1, in one or more example embodiments, the display device 100 may include a display panel 110 in which a plurality of gate lines GL and a plurality of data lines DL are disposed, and a plurality of subpixels SP are arranged in a matrix form, a gate driving circuit 120 configured to drive the plurality of gate lines GL, a data driving circuit 130 configured to supply data voltages through the plurality of data lines DL, a controller 140 configured to control the gate driving circuit 120 and the data driving circuit 130, and a power management circuit 150.

The display panel 110 may be configured to display images based on one or more scan signals and one or more emission control signals transmitted from the gate driving circuit 120 through the plurality of gate lines GL and data voltages transmitted from the data driving circuit 130 through the plurality of data lines DL.

In one or more aspects, in an example where the display device 100 is implemented as a liquid crystal display, the display panel 110 may include a liquid crystal layer formed between two substrates, and operate in one or more operating modes, such as a twisted nematic (TN) mode, a vertical alignment (VA) mode, an in-plane switching (IPS) mode, and/or a fringe field switching (FFS) mode. In one or more aspects, in an example where the display device 100 is implemented as a self-emissive display device such as an organic light emitting display or the like, the display panel 110 may be implemented in a top emission structure, a bottom emission structure, or a dual direction emission structure.

The display panel 110 may have a structure where a plurality of pixels are arranged in a matrix form. Each of the plurality of pixels may include subpixels SP configured to emit light of two or more different colors, and for example, include at least two of a white subpixel, a red subpixel, a green subpixel, and/or a blue subpixel. Each of the plurality of pixels may be defined by one or more data lines DL and one or more gate lines GL.

One subpixel SP may include at least one thin film transistor (TFT) formed in an area where a data line DL and at least one gate line GL intersect, a light emitting element, such as an organic light emitting diode or the like, configured to emit light corresponding a data voltage, a storage capacitor electrically connected to the light emitting element and configured to maintain a voltage at a certain level, and the like.

The gate driving circuit 120, which may be controlled by the controller 140, can control driving timing for a plurality of subpixels SP by sequentially outputting scan signals to a plurality of gate lines GL disposed in the display panel 110.

For example, the gate driving circuit 120 may include one or more gate driving integrated circuits GDIC, and be located in one or more edges of the display panel 110 or only in one edge thereof depending on design requirements. In one or more aspects, the gate driving circuit 120 may be implemented in a gate-in-panel (GIP) structure. In this configuration, the gate driving circuit 120 may be disposed in a bezel area of the display panel 110.

The data driving circuit 130 can receive image data DATA from the controller 140, and convert the received image data DATA into analog data voltages. Thereafter, the data driving circuit 130 can output the data voltages to a plurality of data lines DL according to timing at which the scan signals are applied through the gate lines GL. According to these configurations, each subpixel SP connected to a corresponding data line DL can present light emitted at luminance corresponding to a data voltage.

For example, the data driving circuit 130 may include one or more source driving integrated circuits SDIC. In this example, each source driving integrated circuit SDIC may be connected to a bonding pad of the display panel 110 or directly disposed in the display panel 110 in a tape-automated-bonding (TAB) structure or in a chip-on-glass (COG) structure.

In one or more aspects, one or more source driving integrated circuits SDIC included in the data driving circuit 130 may be mounted on one or more respective source films SF. In this configuration, one side of the source film SF on which the source driving integrated circuit SDIC is mounted may be electrically connected to the display panel 110. In one or more aspects, one or more corresponding signal lines for electrically connecting the one or more source driving integrated circuits SDIC and the display panel 110 to each other may be respectively disposed in one or more corresponding upper portions of the one or more source films SF.

In one or more aspects, each source driving integrated circuit SDIC may be disposed to be integrated into the display panel 110. In one or more aspects, each source driving integrated circuit SDIC may be implemented in the display panel 110 in a chip-on-film (COF) structure. In this configuration, each source driving integrated circuit SDIC may be mounted on a circuit film and electrically connected to a data line DL of the display panel 110 through the circuit film. The one or more source driving integrated circuits SDIC can supply corresponding data voltage(s) to the display panel 110.

The controller 140 can supply various control signals to the gate driving circuit 120 and the data driving circuit 130, and control operations of the gate driving circuit 120 and the data driving circuit 130. For example, the controller 140 can cause the gate driving circuit 120 to output scan signals at timings set for scanning corresponding one or more pixels. Further, the controller 140 can receive image data from an external device or system (e.g., a host system 160), and transmit the received image data or data signals corresponding the received image data to the data driving circuit 130.

For example, the controller 140 can receive various timing signals including a vertical synchronization signal Vsync, a horizontal synchronization signal Hsync, a data enable signal DE, a main clock MCLK, and the like, along with image data from the host system 160.

The host system 160 may be any one of a television (TV), a set top box, a navigation system, a personal computer (PC), a home theater system, a mobile device, a wearable device, and the like.

The controller 140 can generate control signals using various timing signals received from the host system 160, and supply the control signals to the gate driving circuit 120 and the data driving circuit 130.

For example, the controller 140 can supply various gate control signals including a gate start pulse GSP, a gate clock GCLK, a gate output enable signal GOE, and the like to control the gate drive circuit 120. The gate start pulse GSP may be used to control one or more timing at which one or more gate drive integrated circuits GDIC included in the gate drive circuit 120 start operating. The gate clock GCLK may be a clock signal commonly input to one or more gate driving integrated circuits GDIC and be used to control a shift timing of a scan signal. The gate output enable signal GOE may be used to indicate timing information of one or more gate driving integrated circuits GDIC.

The controller 140 can supply various data control signals including a source start pulse SSP, a source sampling clock SCLK, a source output enable signal SOE, and the like to control the data driving circuit 130. The source start pulse SSP may be used to control one or more timing at which one or more source driving integrated circuits SDIC included in the data driving circuit 130 start data sampling. The source sampling clock SCLK may be a clock signal for controlling one or more timing at which one or more source driving integrated circuits SDIC sample data. The source output enable signal SOE may be used to control an output timing of the data driving circuit 130.

The display device 100 may include a power management circuit 150 configured to supply various voltages or currents to the display panel 110, the gate driving circuit 120, the data driving circuit 130, and the like, or to control various voltages or currents to be supplied thereto.

The power management circuit 150 can adjust a DC input voltage Vin supplied by the host system 160 and generate voltages or currents needed for driving the display panel 110, the gate driving circuit 120, and the data driving circuit 130.

Meanwhile, each subpixel SP may be located at a location at which at least one corresponding gate line GL and a corresponding data line DL intersect each other, and a light emitting element such an organic light emitting diode may be disposed in each subpixel SP. In an example where the display device 100 is implemented as an organic light emitting display device including organic light emitting elements such as organic light emitting diodes or the like, the display device 100 may include light emitting elements disposed in subpixels SP, and can display images by controlling current flowing to the light emitting elements according to data voltages.

In one or more aspects, the display device 100 may be various types of devices such as a liquid crystal display (LCD), an organic light emitting diode (OLED) display, a plasma display panel (PDP), a light emitting diode (LED) display, or a quantum dot (QD) light emitting display, and the like.

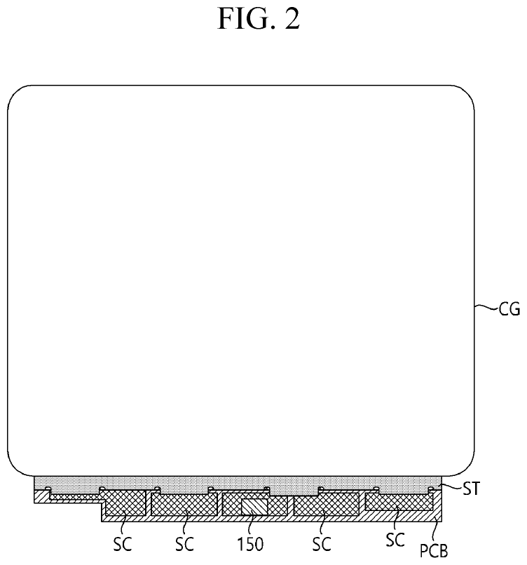

FIG. 2 is an example front view of the display device 100 in an unbent state according to aspects of the present disclosure.

Referring to FIG. 2, in one or more example embodiments, the display device 100 may include a cover glass CG, a shield tape ST, at least one shield can SC, a power management circuit 150, and a printed circuit board PCB.

The cover glass CG may cover the display panel 110. The cover glass CG may be located in an upper portion of the display device 100. For example, the cover glass CG may be located at the top thereof. According to this configuration, the display panel 110 can be protected from external impact. The cover glass CG may include a plastic material having properties of allowing light to be transmitted, or include glass or a material including the glass.

The shield tape ST may overlap with at least a corresponding portion of at least one of at least one source film, the printed circuit board PCB, or the at least one shield can SC. For example, an adhesive or a material including the adhesive may be applied to the rear surface of the shield tape ST. The shield tape ST may be attached to other components (e.g., the at least one source film, the at least one shield can SC, and/or the like) through the adhesive or the material including the adhesive applied to the shield tape ST.

The shield tape ST may include at least one step portion and at least one protrusion portion.

At least a corresponding portion of the at least one protrusion portion may overlap with at least a corresponding portion of the at least one shield can SC. According to this configuration, at least one power line connected from the at least one shield can SC to the at least one source film can be protected from external electromagnetic interference.

For example, two step portions may be disposed on both sides of a corresponding protrusion portion. For example, the two step portions may be formed in respective areas where portions of the shield tape ST are removed.

As the step portions are formed on both sides of the corresponding protrusion portion, the shield tape ST can be reduced or minimized from being torn due to a step difference between the printed circuit board PCB and the at least one shield can SC

The at least one shield can SC may overlap with at least one circuit for driving the display panel 110 disposed on the printed circuit board PCB. For example, the at least one shield can SC may cover the controller 140. For example, a plurality of shield cans SC may be disposed on the printed circuit board PCB. For example, each of the plurality of shield cans SC may surround at least one circuit.

As at least one shield cans SC covers at least one circuit disposed on the printed circuit board PCB, the at least one circuit disposed on the printed circuit board PCB can be protected from external impact, frequency interference, signal interference, electromagnetic interference, and the like. In one or more aspects, at least one shield can SC may serve as at least one path for dissipating heat emitted from at least one driving circuits on the printed circuit board PCB.

For example, the controller 140 may be disposed between the printed circuit board PCB and the at least one shield can SC, and thereby, can be protected from external impact and electromagnetic interference.

For example, the power management circuit 150 may be disposed on the at least one shield can SC. Since the power management circuit 150 supplies voltages or currents, heat may be generated. To address this issue, the power management circuit 150 may be disposed on a shield can SC instead of a structure where the shield can SC surrounds the power management circuit 150 to dissipate heat from the power management circuit 150.

Further, since heat is generated from the controller 140, the controller 140 may be disposed inside of another shield can SC except for the shield can SC disposed under the power management circuit 150.

For example, the controller 140 and the power management circuit 150, which generate heat, may be disposed such that they do not overlap with each other.

The controller 140, the power management circuit 150, at least one shift register, and a plurality of capacitors may be disposed on the printed circuit board PCB. For example, a plurality of circuits or devices for driving the display panel 110 may be mounted on the printed circuit board PCB.

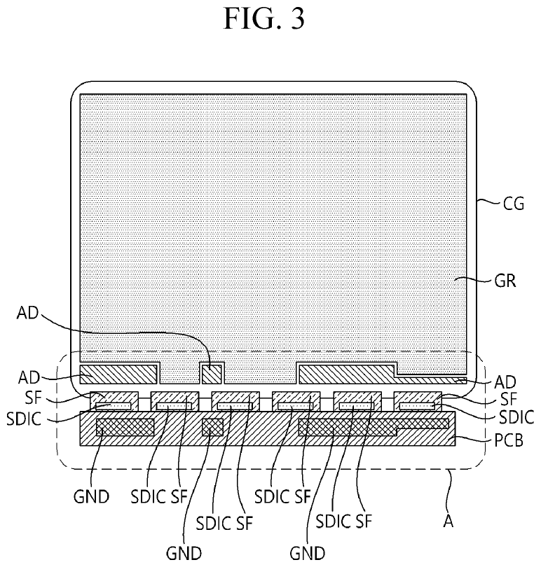

FIG. 3 is an example rear view of the display device 100 in the unbent state according to aspects of the present disclosure.

For example, FIG. 3 may be an illustration of the display device 100 in a state where FIG. 2 is rotated by 180 degrees to the right or left.

Referring to FIG. 3, the display device 100 may include the cover glass CG, a heat disperser GR, at least one adhesive AD, at least one source film SF, at least one source driving integrated circuit SDIC, at least one ground GND, and the printed circuit board PCB.

In discussions that follow for the configuration of FIG. 3, features equal, substantially equal, or similar to the features described with reference to FIGS. 1 and 2 may not be repeatedly described or briefly described for convenience of description.

The heat disperser GR may overlap with the cover glass CG. The heat disperser GR may include a material with thermal conductivity. For example, the heat disperser GR may include graphite. According to this configuration, the heat disperser GR can disperse or transfer heat generated from the printed circuit board PCB.

For example, the heat disperser GR may include a rigid material. According to this configuration, the heat disperser GR can ensure the rigidity of the display device 100.

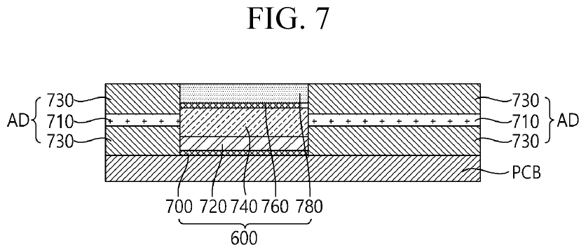

When the at least one source film SF or the printed circuit board PCB is bent, the adhesive AD can attach the printed circuit board PCB to one or more other components (e.g., the display panel 110, a support, and the like). For example, the adhesive AD may include a pressure-sensitive adhesive or a conductive adhesive. Detailed discussions on the adhesive AD are provided with reference to FIG. 7 below.

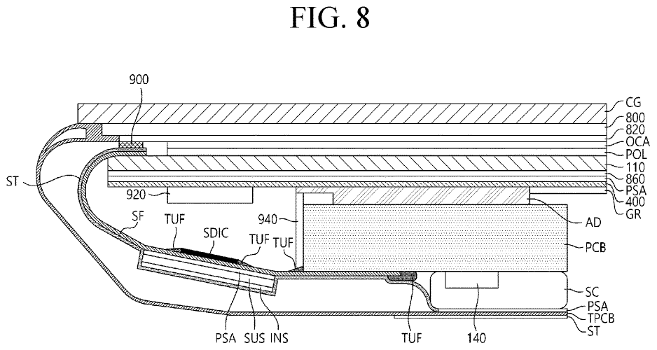

The at least one source film SF may be bent and placed on the rear surface of the display device 100. According to this configuration, the display device 100 can realize a narrow bezel. Detailed discussions on this configuration are provided with reference to FIG. 8 below.

At least a portion of the printed circuit board PCB may overlap with the at least one source film SF. For example, the printed circuit board PCB may be attached on the at least one source film SF.

The ground GND may be disposed on the printed circuit board PCB. The ground GND may provide electrical stability. The ground GND may be disposed at an area corresponding to an area where the adhesive AD is disposed and have a shape corresponding to the shape of the adhesive AD. According to this configuration, when the at least one source film SF or the printed circuit board PCB is bent, the ground GND and the adhesive AD can be attached to each other.

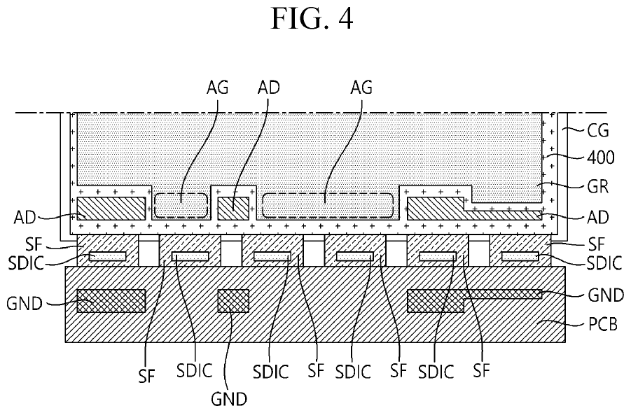

FIG. 4 is an example enlarged view of area A of FIG. 3 according to aspects of the present disclosure.

Referring to FIG. 4, the display device 100 may include the cover glass CG, a support 400, the heat disperser GR, the at least one adhesive AD, the at least one source film SF, the at least one source driving integrated circuit SDIC, the at least one ground GND, and the printed circuit board PCB.

In discussions that follow for the configuration of FIG. 4, features equal, substantially equal, or similar to the features described with reference to FIGS. 1 to 3 may not be repeatedly described or briefly described for convenience of description.

The support 400 can ensure the rigidity of the display device 100. The support 400 may include copper, or stainless steel or a material including the stainless steel.

As the printed circuit board PCB is bent toward the rear surface of the display device 100, the printed circuit board PCB and components (e.g., the controller 140, the power management circuit 150, the at least one shield can SC, and the at least one ground GND) disposed on the printed circuit board PCB may be located on the rear surface of the display device 100.

As a plurality of adhesives AD having a smaller area than the printed circuit board PCB attach the back surface of the display device 100 and the printed circuit board PCB to each other, an air gap AG may be formed in an area where the adhesives AD are not disposed.

Heat generated from components (e.g., the controller 140 and the power management circuit 150) disposed on the printed circuit board PCB may be transferred to the air gap AG.

Heat transferred to the air gap AG may be transferred to a plurality of subpixels SP in the display panel 110.

When heat is transferred to the subpixels SP, there may occur degradation of optical characteristics, an increase in the mobility of thin film transistors included in the subpixels, and a deviation in luminance of presented images.

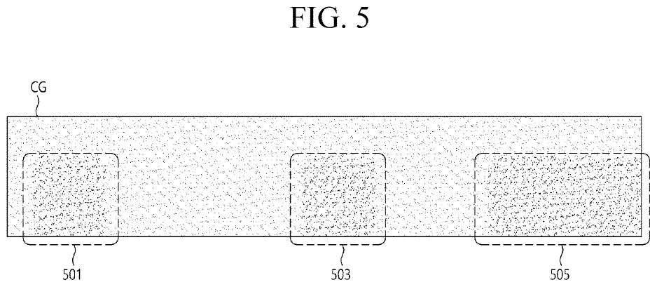

Detailed discussions on this are provided with reference to FIGS. 5, 10, and 11 below.

Hereinafter, discussions are provided for a viewing surface of a display device 100 while a luminance deviation occurs.

FIG. 5 illustrates an example viewing surface of the display device 100 according to aspects of the present disclosure.

Referring to FIG. 5, a cover glass CG may be disposed at an outermost edge of the viewing surface of the display device 100.

For example, when heat is transferred to subpixels SP disposed in a first area 501, a second area 503, and a third area 505 of the display device 100, these areas 501 to 503 may be areas where the subpixels SP have degraded due to the heat transfer.

As a result, images with unintended luminance may be presented in the first area 501, the second area 503, and the third area 505.

Hereinafter, discussions are provided for examples where a heat insulator for reducing or preventing the degradation of subpixels SP is disposed in the display device 100.

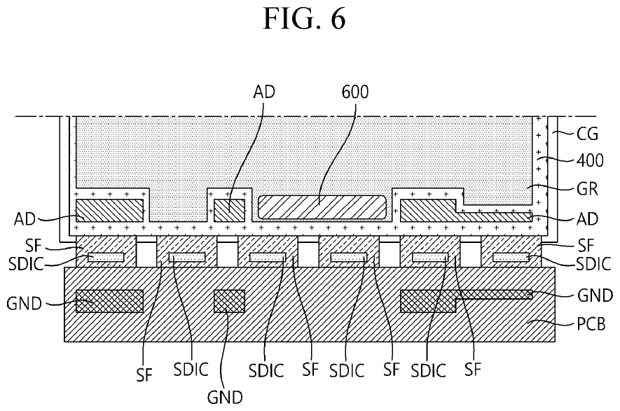

FIG. 6 is an enlarged view of area A of FIG. 3 based on an example where the display device includes a heat insulator according to aspects of the present disclosure

Referring to FIG. 6, the display device 100 may include the cover glass CG, the support 400, the heat disperser GR, the at least one adhesive AD, the at least one source film SF, the at least one source driving integrated circuit SDIC, the at least one ground GND, the printed circuit board PCB, and a heat insulator 600.

In discussions that follow for the configuration of FIG. 6, features equal, substantially equal, or similar to the features described with reference to FIGS. 1 to 5 may not be repeatedly described or briefly described for convenience of description.

The heat insulator 600 can block heat transferred to the heat insulator 600. For example, when heat generated from the power management circuit 150 is transferred to the heat insulator 600, the heat insulator 600 may not transfer the transferred heat to the display panel 110.

For example, when the at least one source film SF or the printed circuit board PCB is bent, the heat insulator 600 may overlap with at least a portion of the power management circuit 150 or at least a portion of the controller 140.

As the heat insulator 600 overlaps with at least a portion of the power management circuit 150 or at least a portion of the controller 140, heat generated from the power management circuit 150 or the controller 140 may be dissipated to the back surface of the display device 100 without being transferred to a plurality of subpixels SP.

For example, the heat insulator 600 may be disposed at a location where an air gap AG is formed. For example, the heat insulator 600 may be located in an area where the likelihood of heat being transferred is high.

For example, the heat insulator 600 may be disposed at at least one of areas where one or more air gaps AG are formed as illustrated in FIG. 4.

For example, a plurality of heat insulators 600 may be disposed at respective areas where a plurality of air gaps AG in FIG. 4 are formed.

Hereinafter, discussions are provided for examples for the configuration of the heat insulator 600.

FIG. 7 illustrates an example arrangement relationship of a printed circuit board (e.g., the printed circuit board PCB), a heat insulator (e.g., the heat insulator 600), and an adhesive (e.g., the adhesive AD) included in the display device 100 according to aspects of the present disclosure.

Referring to FIG. 7, the display device 100 may include the printed circuit board PCB, the heat insulator 600, and the adhesive AD.

When the display device 100 is bent, the heat insulator 600 and the adhesive AD may overlap with the printed circuit board PCB.

The adhesive AD may be disposed on at least one side surface of the heat insulator 600.

The adhesive AD may be disposed between the display panel 110 and the printed circuit board PCB.

The adhesive AD may include a metal layer 710 and a plurality of adhesive layers 730.

The plurality of adhesive layers 730 may include an adhesive layer PSA attached to the printed circuit board PCB and the metal layer 710, and an adhesive layer PSA that is not attached to the printed circuit board PCB but is attached to the metal layer 710.

The adhesive layer PSA attached to the printed circuit board PCB and the metal layer 710 may be referred to as a first adhesive layer. The adhesive layer PSA, which is not attached to the printed circuit board PCB but is attached to the metal layer 710, may be referred to as a second adhesive layer. The second adhesive layer may be disposed between the display panel 110 and the first adhesive layer.

For example, the adhesive layer PSA may include a conductive pressure-sensitive adhesive (CPSA).

For example, the metal layer 710 may include copper.

The adhesive layer 730 may have a thickness greater than that of the metal layer 710. For example, the thickness of the adhesive layer 730 may be 20 times the thickness of the metal layer 710.

The heat insulator 600 may include a single-sided adhesive 700, a heat dissipator 720, a heat shielder 740, a double-sided adhesive 760, and an impact absorber 780.

The single-sided adhesive 700 may bond the printed circuit board PCB and the heat dissipator 720 to each other. For example, the single-sided adhesive 700 may be a black single-sided adhesive.

For example, the single-sided adhesive 700 may have a thickness greater than that of the double-sided adhesive 760. The single-sided adhesive 700 may have a thickness smaller than that of each of the heat dissipator 720, the heat shielder 740, and the impact absorber 780.

The heat dissipator 720 may be disposed on the printed circuit board PCB. For example, the heat dissipator 720 may be attached to the printed circuit board PCB via the single-sided adhesive 700.

The heat dissipator 720 can transfer heat to one or more other components. The heat dissipator 720 may include a thermally conductive material. For example, the heat dissipator 720 may include graphite or a material including the graphite.

For example, the heat dissipator 720 may have a thickness greater than that of each of the single-sided adhesive 700 and the double-sided adhesive 760. The heat dissipator 720 may have the same or substantially same thickness as the impact absorber 780. The heat dissipator 720 may have a thickness smaller than that of the heat shielder 740.

The heat shielder 740 may be disposed on the heat dissipator 720.

The heat shielder 740 can block heat transfer. For example, when heat generated in the power management circuit 150 is transferred to the heat shielder 740, the heat shielder 740 can shield the heat, and thereby reduce or prevent heat from being transferred to the display panel 110. As a result, the degradation of subpixels SP can be reduced or prevented.

The heat shielder 740 may have a thickness greater than that of each of the single-sided adhesive 700, the heat dissipator 720, the double-sided adhesive 760, and the shock absorbor 780.

The double-sided adhesive 760 may be disposed on the heat shielder 740.

The double-sided adhesive 760 may attach the heat shielder 740 and the impact absorber 780 to each other.

The double-sided adhesive 760 may have a thickness smaller than that of each of the single-sided adhesive 700, the heat dissipator 720, the heat shielder 740, and the impact absorber 780.

For example, the impact absorber 780 may be disposed on the heat shielder 740. For example, the impact absorber 780 may be attached to the heat shielder 740 via the double-sided adhesive 760.

The impact absorber 780 can serve to mitigate external impact. According to this configuration, damage to other components of the display device 100 (e.g., the display panel 110, the printed circuit board PCB, and the like) from external impact can be reduced or minimized. Further, the durability of the heat insulator 600 can be improved.

For example, the impact absorber 780 may include polyurethane (PU), a material including the polyurethane (PU), or the like.

FIG. 8 is an example cross-sectional view of the display device 100 in a bent state in an area where an adhesive (e.g., the adhesive AD) is disposed according to aspects of the present disclosure.

Referring to FIG. 8, the display device 100 may include a cover glass CG, a first touch sensor layer 800, a second touch sensor layer 820, an optical adhesive OCA, a polarizer POL, the display panel 110, a coating layer 860, an adhesive layer PSA, a support 400, a heat disperser GR, an adhesive AD, a printed circuit board PCB, a guide 940, the controller 140, at least one shield can SC, a touch printed circuit board TPCB, a shield tape ST, a buffer TUF, a gap filler 900, an external force eraser 920, at least one source film SF, at least one source driving integrated circuit SDIC, a reinforcer SUS, and an insulator INS.

In discussions that follow for the configuration of FIG. 8, features equal, substantially equal, or similar to the features described with reference to FIGS. 1 to 7 may not be repeatedly described or briefly described for convenience of description.

The cover glass CG may cover the first touch sensor layer 800, the second touch sensor layer 820, the polarizer POL, and the display panel 110. The cover glass CG may be located in an upper portion of the display device 100. For example, the cover glass CG may be located at the top thereof. According to this configuration, other components (e.g., the first touch sensor layer 800, the second touch sensor layer 820, the polarizer POL, and the display panel 110) can be protected from external impact. The cover glass CG may include a plastic material having properties of allowing light to be transmitted, or include glass or a material including the glass.

The first touch sensor layer 800 may be disposed on the second touch sensor layer 820. The first touch sensor layer 800 may include an indium tin oxide. For example, the first touch sensor layer 800 may be in the form of a double layer of indium tin oxide.

The second touch sensor layer 820 may be disposed on the polarizer POL. For example, the second touch sensor layer 820 may be attached to the polarizer POL via the optical adhesive OCA.

The second touch sensor layer 820 may include an indium tin oxide. For example, the second touch sensor layer 820 may be in the form of a single layer of indium tin oxide. The second touch sensor layer 820 can reduce or prevent noise generated in the first touch sensor layer 800.

Since the first touch sensor layer 800 is in the form of the double layer of indium tin oxide, and the second touch sensor layer 820 is in the form of the single layer of indium tin oxide, the structure of a dual touch sensor layer may be formed in the display device 100.

The display device 100 can present advantages of improving the accuracy of touch recognition, reducing costs, and optimizing power consumption based on the structure of the dual touch sensor layer.

The optical adhesive OCA can attach the second touch sensor layer 820 and the polarizer POL to each other.

For example, the optical adhesive OCA may include a material with transparent and/or adhesive properties. For example, the optical adhesive OCA can protect the polarizer POL from external impact.

The polarizer POL may be disposed on the display panel 110.

The polarizer POL can reduce or prevent externally incident light from entering the display panel 110 and being reflected. The polarizer POL can reduce or prevent the reflection of incident light, and thereby reducing or preventing the visibility of the display panel 110 from being reduced.

The display panel 110 may be disposed on the coating layer 860.

For example, the display panel 110 may include a plurality of subpixels SP, at least one thin film transistor for driving the plurality of subpixels, and a plurality of insulating layers.

The coating layer 860 may be disposed on the adhesive AD or the heat disperser GR. The coating layer 860 may help the rigidity of the display panel 110.

The adhesive layer PSA may be disposed between different components to attach these components. The adhesive layer PSA may include a pressure-sensitive adhesive.

For example, the adhesive layer PSA may be disposed between the coating layer 860 and the heat disperser GR. According to this configuration, the coating layer 860 and the heat disperser GR may be attached to each other.

For example, the adhesive layer PSA may be disposed between the shield can SC and the touch printed circuit board TPCB. According to this configuration, the shield can SC and the touch printed circuit board TPCB may be attached to each other.

For example, the adhesive layer PSA may be disposed between the source film SF and the reinforcer SUS. According to this configuration, the source film SF and the reinforcer SUS may be attached to each other.

The heat disperser GR may dissipate heat transferred from the printed circuit board PCB to the rear surface of the display device 100.

The support 400 can help the rigidity of the display panel 110.

The adhesive AD may attach the printed circuit board PCB and the support 400 to each other.

For example, the adhesive AD may attach the rear surface of the printed circuit board PCB and the support 400 to each other. According to this configuration, as the printed circuit board PCB is disposed on a surface facing the viewing surface of the display panel 110, the display device 100 or display panel 110 can present an advantage of implementing a narrow bezel.

For example, the adhesive AD can attach the ground GND and the support 400 to each other. For example, the ground GND may be disposed between the adhesive AD and the printed circuit board PCB.

Circuits for driving the display panel 110, such as capacitors, the controller 140, and shift registers, may be dispose on the printed circuit board PCB.

The guide 940 can guide a location of the printed circuit board PCB.

The controller 140 may be disposed on the printed circuit board PCB. For example, the controller 140 may overlap with at least a portion of the adhesive AD.

The shield can SC may be disposed on the printed circuit board PCB such that the shield can SC surrounds the controller 140. According to this configuration, the controller 140 can be protected from external electromagnetic interference and impact.

The touch printed circuit board TPCB may be bent and overlap with the shield can SC. The touch printed circuit board TPCB may be electrically connected to the first touch sensor layer 800 and the second touch sensor layer 820. The touch printed circuit board TPCB may be electrically connected to a touch controller configured to detect a touch input and control an operation in response to the touch input.

The shield tape ST may be overlapped with at least a portion of the touch printed circuit board TPCB. According to this configuration, the at least a portion of the touch printed circuit board TPCB can be protected from electromagnetic interference and external forces.

The source film SF may be overlapped with the display panel 110 and be electrically connected to the display panel 110. The source film SF may be referred to as a chip-on-film (COF).

The source driving integrated circuit SDIC may be disposed on the source film SF. A voltage generated from the source driving integrated circuit SDIC may be provided to the display panel 110. The voltage generated from the source driving integrated circuit SDIC may be a variable voltage. Further, the voltage generated from the source driving integrated circuit SDIC may be a data voltage.

The source film SF may be electrically connected to a pad portion of the display panel 110. The source film SF may include a bendable material. As the source film SF is bent, the display device 100 can present an advantage of allowing a narrow bezel to be implemented.

The source film SF may overlap with at least a portion of the printed circuit board PCB. Current and voltage generated from circuits of the printed circuit board PCB may be supplied to the display panel 110 through the source film SF. For example, various voltages and/or currents supplied to the display panel 110 from the power management circuit 150 or controller 140 may be supplied through the source film SF.

The shield tape ST may be overlapped with the source film SF. The shield tape ST can protect the source film SF from external electromagnetic interference.

A gap may be formed between the source film SF or the shield tape ST and the second touch sensor layer 820.

Due to the gap, impact may be applied to at least a portion of the source film SF or the second touch sensor layer 820. To reduce or prevent such impact, the gap filler 900 may be disposed in the gap.

For example, the gap filler 900 may include a resin or a material including the resin.

When the source film SF moves, the source driver integrated circuit SDIC may come into contact with another component, such as the support 400. To reduce or prevent the source driver integrated circuit SDIC from being damaged due to impact, the external force eraser 920 may be disposed.

The external force eraser 920 may be overlapped with at least a portion of the support 400. The external force eraser 920 may overlap with the source drive integrated circuit SDIC.

The external force eraser 920 may include urethane foam PU.

The buffer TUF may include a resin. The buffer TUF can improve adhesion between components. The buffer TUF can reduce or minimize light leakage. The buffer TUF can reduce or minimize the penetration of undesired or external substances.

For example, the buffer TUF may be disposed in an area adjacent to the display panel 110 and the source film SF.

For example, the buffer TUF may be disposed on both sides of the source driving integrated circuit SDIC.

For example, the buffer TUF may be disposed in an area adjacent to the guide 940, the printed circuit board PCB, and the source film SF.

For example, the buffer TUF may be disposed in an area adjacent to the source film SF, the printed circuit board PCB, and the shield tape ST.

The reinforcer SUS may be attached to the source film SF by the adhesive layer PSA. The reinforcer SUS may be overlapped with the source driving integrated circuit SDIC.

The reinforcer SUS can protect the source drive integrated circuit SDIC from external impact and help the rigidity thereof. The reinforcer SUS may include stainless steel or a material including the stainless steel.

The insulator INS may be disposed between the reinforcer SUS and the shield tape ST.

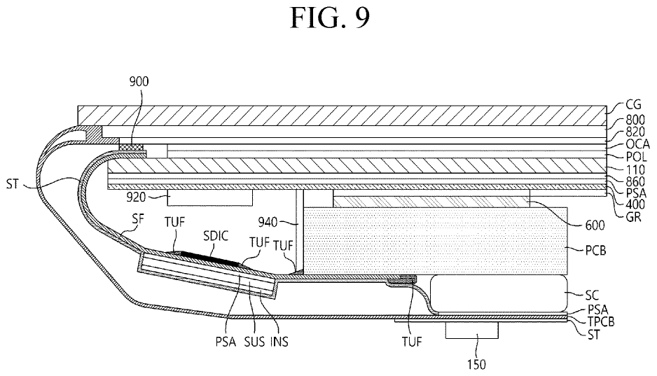

FIG. 9 is an example cross-sectional of the display device 100 in a bent state in an area where the heat insulator 600 is disposed according to aspects of the present disclosure.

Referring to FIG. 9, the display device 100 may include a cover glass (e.g., the cover glass CG), a first touch sensor layer (e.g., the first touch sensor layer 800), a second touch sensor layer (e.g., the second touch sensor layer 820), an optical adhesive (e.g., the optical adhesive OCA), a polarizer (e.g., the polarizer POL), the display panel 110, a coating layer (e.g., the coating layer 860), an adhesive layer (e.g., the adhesive layer PSA), a support (e.g., the support 400), a heat disperser (e.g., the heat disperser GR), a heat insulator (e.g., the heat insulator 600), a printed circuit board (e.g., the printed circuit board PCB), a guide (e.g., the guide 940), the power management circuit 150, at least one shield can (e.g., the at least one shield can SC), a touch printed circuit board (e.g., the touch printed circuit board TPCB), a shield tape (e.g., the shield tape ST), a buffer (e.g., the buffer TUF), a gap filler (e.g., the gap filler 900), an external force eraser (e.g., the external force eraser 920), at least one source film (e.g., the at least one source film SF), a source driving integrated circuit (e.g., the source driving integrated circuit SDIC), a reinforcer (e.g., the reinforcer SUS), and an insulator (e.g., the insulator INS).

In discussions that follow for the configuration of FIG. 9, features equal, substantially equal, or similar to the features described with reference to FIGS. 1 to 8 may not be repeatedly described or briefly described for convenience of description.

The heat insulator 600 may be disposed between the heat disperser GR and the printed circuit board PCB. For example, the heat insulator 600 may be disposed between the display panel 110 and the printed circuit board PCB.

According to this configuration, heat generated from circuits disposed on the printed circuit board PCB may not be transferred to the display panel 110.

As heat is not transferred to the display panel 110, the display device 100 or the display panel 110 can present an advantage of reducing or minimizing defects caused by heat transferred to subpixels SP.

For example, the power management circuit 150 may be overlapped with at least a portion of the heat insulator 600. According to this configuration, heat generated by the power management circuit 150 may not be transferred to the display panel 110.

For example, the power management circuit 150 may be disposed outside of the shield can SC. For example, the power management circuit 150 may be overlapped with the shield can SC. According to this configuration, the shield can SC may be reduced or prevented from interfering with heat dissipation.

The controller 140 in FIG. 8 may be also overlapped with at least a portion of the heat insulator 600. According to this configuration, heat generated by the controller 140 may not be transferred to the display panel 110.

For example, a cooling device may be disposed in an area adjacent to the power management circuit 150. According to this configuration, the heat generated in the power management circuit 150 may be transferred less to the display panel 110 and more to the rear of the display device 100.

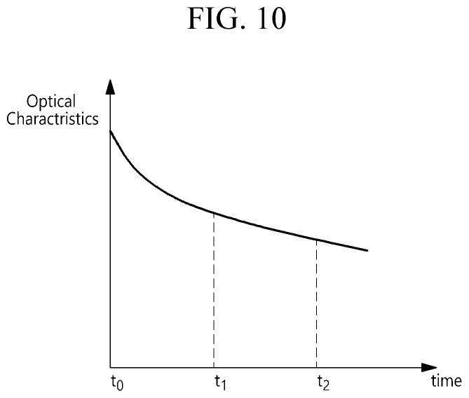

FIG. 10 is an example graph showing changes in optical characteristics over heat generation time according to aspects of the present disclosure.

Referring to FIG. 10, the horizontal axis of the graph may represent heat generation time, and the vertical axis of the graph may represent optical characteristics. The vertical axis of the graph may be designed so that a higher value indicates better optical characteristics.

The optical characteristics may include at least one of luminance, a contrast ratio, color accuracy, color reproducibility, a viewing angle, a reflectivity, a transmittance, mobility of driving transistors included subpixels SP, or an incident angle.

At an initial time point t0, heat may not be transferred to the display panel 110. Therefore, corresponding optical characteristics may be optimal

At a first time point t1 after the initial time point t0, a corresponding thin film transistor may be at 25 degrees. Therefore, the optical characteristics may deteriorate or be lowered.

At a second time point t2 after the first time point t1, the thin film transistor may be at 60 degrees. Therefore, the optical characteristics may further deteriorate or be lowered. For example, as time passes from the first time point t1 to the second time point t2, when the temperature of the display panel 110 increases, the mobility of the thin film transistor (e.g., a driving transistor) may increase by 30%.

As a result, the optical characteristics may deteriorate or be lowered. Thus, the degradation of subpixels SP and the deterioration of corresponding optical characteristics may be caused depending on heat generated from circuits disposed on the printed circuit board PCB.

Hereinafter, discussions are provided for temperature changes depending on the presence or absence of the heat insulator 600.

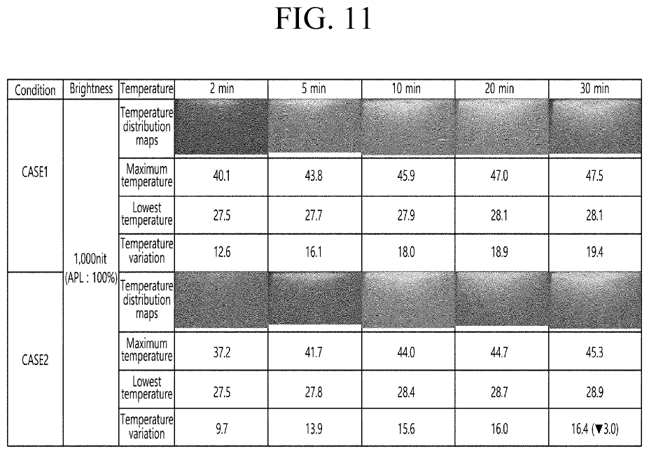

FIG. 11 is an example diagram showing changes in temperature of the display device 100 depending on the presence or absence of a heat insulator (e.g., the heat insulator 600) according to aspects of the present disclosure.

Referring to FIG. 11, a first case CASE1 may represent an example of the display device 100 without a heat insulator 600. A second case CASE2 may represent an example of the display device 100 with the heat insulator 600.

For example, the maximum temperature may be the highest temperature of the display panel 110 in each of the first case CASE1 or the second case CASE2 The lowest temperature may be the lowest temperature of the display panel 110 in each of the first case CASE1 or the second case CASE2. Temperature variations may be differences between the highest temperature and the lowest temperature of the display panel 110 in each of the first case CASE1 or the second case CASE2.

For example, the temperature of the display device 100 in the first case CASE1 and the temperature of the display device 100 in the second case CASE2 may represent respective temperature values measured in a brightness condition corresponding to 1000 NIT.

For example, temperature distribution maps may be maps visualizing the distribution of respective temperature values measured in the display panel 110 in each of the first case CASE1 and the second case CASE2.

The temperature distribution maps may include maps visualized at 2 minutes, 5 minutes, 10 minutes, 20 minutes, and 30 minutes after heat is transferred to the display panel 110 in each of the first case CASE1 and the second case CASE2.

When comparing the temperature distribution map representing the first case CASE1 and the temperature distribution map representing the second case CASE2, it can be seen that temperature rises and spreads more rapidly in the temperature distribution map representing the first case CASE1 than in the temperature distribution map representing the second case CASE2.

For example, when heat is transferred to the display panel 110 and 2 minutes have passed, the maximum temperature and the lowest temperature of the first case CASE1 may be 40.1 degrees and 27.5 degrees, respectively. In this example, a temperature variation may be 12.6 degrees. The temperature distribution may represent a difference between the maximum temperature and the lowest temperature.

For example, when heat is transferred to the display panel 110 and 2 minutes have passed, the maximum temperature and the lowest temperature of the second case CASE2 may be 37.2 degrees and 27.5 degrees, respectively. In this example, a temperature variation may be 9.7 degrees.

Thus, as the heat insulator 600 is disposed, when heat is transferred to the display panel 110 and 2 minutes have passed, the maximum temperature and temperature variation of the second case CASE2 may be lower than the maximum temperature and temperature variation of the first case CASE1.

For example, when heat is transferred to the display panel 110 and 5 minutes have passed, the maximum temperature and the lowest temperature of the first case CASE1 may be 43.8 degrees and 27.7 degrees, respectively. In this example, a temperature variation may be 16.1 degrees.

For example, when heat is transferred to the display panel 110 and 5 minutes have passed, the maximum temperature and the lowest temperature of the second case CASE2 may be 41.7 degrees and 27.8 degrees, respectively. In this example, a temperature variation may be 13.9 degrees.

Thus, as the heat insulator 600 is disposed, when heat is transferred to the display panel 110 and 5 minutes have passed, the maximum temperature and temperature variation of the second case CASE2 may be lower than the maximum temperature and temperature variation of the first case CASE1.

For example, when heat is transferred to the display panel 110 and 10 minutes have passed, the maximum temperature and the lowest temperature of the first case CASE1 may be 45.9 degrees and 27.9 degrees, respectively. In this example, a temperature variation may be 18.0 degrees.

For example, when heat is transferred to the display panel 110 and 10 minutes have passed, the maximum temperature and the lowest temperature of the second case CASE2 may be 44.0 degrees and 28.4 degrees, respectively. In this example, a temperature variation may be 15.6 degrees.

Thus, as the heat insulator 600 is disposed, when heat is transferred to the display panel 110 and 20 minutes have passed, the maximum temperature and temperature variation of the second case CASE2 may be lower than the maximum temperature and temperature variation of the first case CASE1.

For example, when heat is transferred to the display panel 110 and 20 minutes have passed, the maximum temperature and the lowest temperature of the first case CASE1 may be 47.0 degrees and 28.1 degrees, respectively. In this example, a temperature variation may be 18.9 degrees.

For example, when heat is transferred to the display panel 110 and 20 minutes have passed, the maximum temperature and the lowest temperature of the second case CASE2 may be 44.7 degrees and 28.7 degrees, respectively. In this example, a temperature variation may be 16.0 degrees.

Thus, as the heat insulator 600 is disposed, when heat is transferred to the display panel 110 and 20 minutes have passed, the maximum temperature and temperature variation of the second case CASE2 may be lower than the maximum temperature and temperature variation of the first case CASE1.

For example, when heat is transferred to the display panel 110 and 30 minutes have passed, the maximum temperature and the lowest temperature of the first case CASE1 may be 47.5 degrees and 28.1 degrees, respectively. In this example, a temperature variation may be 19.4 degrees.

For example, when heat is transferred to the display panel 110 and 30 minutes have passed, the maximum temperature and the lowest temperature of the second case CASE2 may be 45.3 degrees and 28.9 degrees, respectively. In this example, a temperature variation may be 16.4 degrees.

Thus, as the heat insulator 600 is disposed, when heat is transferred to the display panel 110 and 30 minutes have passed, the maximum temperature and temperature variation of the second case CASE2 may be lower than the maximum temperature and temperature variation of the first case CASE1.

In particular, as time passes after heat is transferred, a difference in temperature variation may tend to increase. For example, when heat is transferred to the display panel 110 and 20 minutes have passed, a difference between respective temperature variations of the first case CASE1 and the second case CASE2 may be 2.9 degrees. For example, when heat is transferred to the display panel 110 and 30 minutes have passed, a difference between respective temperature variations of the first case CASE1 and the second case CASE2 may be 3 degrees.

The examples, aspects, and embodiments for the display device 100 and the display panel 110 described herein may be described as follows.

According to the one or more example embodiments described herein, a display device can be provided that includes a display panel in which a plurality of subpixels are disposed, a power management circuit for supplying one or more driving voltages to the plurality of subpixels, a printed circuit board disposed to overlap with the power management circuit, and a heat insulator disposed between the printed circuit board and the display panel and overlapping with at least a portion of the power management circuit.

In one or more aspects, the heat insulator may include a heat dissipator attached to the printed circuit board and dissipating heat, a heat shielder overlapping with the heat dissipator and shielding heat, and an impact absorber overlapping with the heat dissipator.

In one or more aspects, the display device may further include an adhesive disposed between the display panel and the printed circuit board.

In one or more aspects, the adhesive may be disposed on at least one side of the heat insulator.

In one or more aspects, the display device may further include a controller configured to provide image data to be supplied to the display panel,

In one or more aspects, at least a portion of the adhesive may overlap with the controller.

In one or more aspects, the adhesive may include a first adhesive layer attached to the printed circuit board, a second adhesive layer disposed between the display panel and the first adhesive layer, and a metal layer disposed between the first adhesive layer and the second adhesive layer.

In one or more aspects, the display device may further include a controller configured to provide image data to be supplied to the display panel and disposed on the printed circuit board, and a shield can for protecting at least a portion of the printed circuit board and the controller.

In one or more aspects, the display device may further include a shield tape attached to at least a portion of the shield can.

In one or more aspects, the display device may further include a shield can disposed on the printed circuit board.

In one or more aspects, wherein the shield may overlap with the power management circuit.

In one or more aspects, the display device may further include a shield tape attached to at least a portion of the shield can.

In one or more aspects, the display device may further include a first touch sensor layer disposed on the display panel, and a second touch sensor layer disposed on the first touch sensor layer.

The above description has been presented to enable any person skilled in the art to make and use the technical idea of the present disclosure, and has been provided in the context of a particular application and its requirements. Various modifications, additions and substitutions to the described embodiments will be readily apparent to those skilled in the art, and the principles described herein may be applied to other embodiments and applications without departing from the scope of the present disclosure. The above description and the accompanying drawings provide an example of the technical idea of the present disclosure for illustrative purposes only. That is, the disclosed embodiments are intended to illustrate the scope of the technical idea of the present disclosure.

What is claimed is:

1. A display device comprising:
a display panel in which a plurality of subpixels are disposed;
a power management circuit configured to supply at least one driving voltage to the plurality of subpixels;
a printed circuit board overlapping with the power management circuit; and
a heat insulator disposed between the printed circuit board and the display panel and overlapping with at least a portion of the power management circuit.

2. The display device of claim 1, wherein the heat insulator comprises:
a heat dissipator attached to the printed circuit board and dissipating heat;
a heat shielder overlapping with the heat dissipator and shielding heat; and
an impact absorber overlapping with the heat dissipator.

3. The display device of claim 1, further comprising: an adhesive disposed between the display panel and the printed circuit board,
wherein the adhesive is disposed on at least one side of the heat insulator.

4. The display device of claim 3, further comprising: a controller configured to provide image data to be supplied to the display panel,
wherein at least a portion of the adhesive overlaps with the controller.

5. The display device of claim 3, wherein the adhesive comprises:
a first adhesive layer attached to the printed circuit board;
a second adhesive layer disposed between the display panel and the first adhesive layer; and
a metal layer disposed between the first adhesive layer and the second adhesive layer.

6. The display device of claim 1, further comprising:
a controller configured to provide image data to be supplied to the display panel and disposed on the printed circuit board; and
a shield can for protecting at least a portion of the printed circuit board and the controller.

7. The display device of claim 6, further comprising: a shield tape attached to at least a portion of the shield can.

8. The display device of claim 1, further comprising: a shield can disposed on the printed circuit board,
wherein the shield can overlaps with the power management circuit.

9. The display device of claim 8, further comprising: a shield tape attached to at least a portion of the shield can.

10. The display device of claim 1, further comprising:
a first touch sensor layer disposed on the display panel; and
a second touch sensor layer disposed on the first touch sensor layer.
